(19) United States
(12) Patent Application Publication
(10) Pub. No.: US 2025/0061248 A1
(43) Pub. Date: Feb. 20, 2025

(54) METHOD AND SYSTEM FOR GENERATION OF SEAT ALLOCATION PLAN

(71) Applicant: JPMorgan Chase Bank, N.A., New York, NY (US)

(72) Inventors: Rui Manuel Ramos Teixeira DA SILVA, London (GB); Anton IPSEN, Manhattan, NY (US); Kirsty FIELDING, Lancashire (GB); Nicolas MARCHESOTTI, London (GB); Michael CASHMORE, Stirlingshire (GB); Daniele MAGAZZENI, London (GB); Manuela VELOSO, New York, NY (US)

(73) Assignee: JPMorgan Chase Bank, N.A., New York, NY (US)

(21) Appl. No.: 18/234,728

(22) Filed: Aug. 16, 2023

(51) Int. Cl. G06F 30/27; G06F 30/12

(52) U.S. Cl. CPC G06F 30/27; G06F 30/12

(57) ABSTRACT

A method and a computing apparatus for generating a seat allocation plan are provided. The method includes: receiving a floorplan that corresponds to a floor of a building; analyzing the floorplan in order to determine a number of seats and to identify locations of the seats and locations of non-seating areas; receiving a first input that includes information that relates to a plurality of persons for which seat allocations are to be made; and determining, based on a result of the analyzing and the first input, a seat allocation plan. The determination of the seat allocation plan may be effected by applying an artificial intelligence (AI) algorithm that implements a Mixed Integer Programming and Constraint Reasoning technique with respect to the result of the analyzing and the first input.

### BACKGROUND

### 1. Field of the Disclosure

This technology generally relates to methods and systems for generating a seat allocation plan, and more particularly to methods and systems for using artificial intelligence techniques to analyze floorplans to identify seating locations and generate a seat allocation plan for a population that uses space efficiently while respecting many different preferences and constraints.

### 2. Background Information

The construction of a new building is linked with the generation of different floorplan settings that may change over time, as business requirements are fine tuned. Moreover, these intermediate floorplans may be generated in non-standard formats and/or come from various sources, rendering it challenging to automatically process them. Further, an existing layout of a given floor may be changed often due to business needs. For example, adding new collaboration spaces or meeting rooms.

Additionally, at the same time, re-allocation of seats to teams may be required for a number of reasons. First, team size changes: The size of the teams may change over time. While some teams may grow, thus requiring more space, others may shrink, thus requiring less seats. Moreover, the number of interns, part-time employees and contractors may also fluctuate with the business needs. As a result, a given seat allocation can quickly become suboptimal as time progresses. As such, it is important to regularly re-allocate seating in a floorplan of a building to more optimally accommodate the new business needs.

Second, temporary changes in space available: A particular seating capacity may change or vary over time. For example, temporary constructions works or remodeling disruptions in the building may change or alter the seating capacity and/or seating locations in the building. This may require the re-allocation of different teams to new spaces.

Third, scenario assessment: The business may wish to explore how repurposing the space to cater for other type of work (e.g., creating a large collaborative space within a floor to encourage large group discussions). This, however, may impact the seat-to-team allocation within a given space.

There are a number of challenges associated with automatically processing floorplan information to optimize space allocations in a floorplan of a building. First, different formats for representing floorplans: The floorplans may come from different sources, and thus, may be in non-standard styles or formats.

Second, large scale of the problem: A typical building may span dozens of floors, with each floor encompassing hundreds of seats. This large scale renders manual approaches to both floorplan processing and seat allocations as time-consuming and error prone.

Third, difficult to reason over different scenarios: The scale and complexity of the problem may make it difficult to generate multiple different solutions for seat allocations in the building, under different constraints and preferences. This may prevent the users from understanding the impact of such constraints/preferences in the final solution, and may ultimately prevent the user from even finding good solutions.

Accordingly, there is a need for a methodology for automatically processing a buildings floorplan to identify seating locations and generate a seat allocation plan for a population.

### SUMMARY

The present disclosure, through one or more of its various aspects, embodiments, and/or specific features or sub-components, provides, inter alia, various systems, servers, devices, methods, media, programs, and platforms for automatically assigning seats to personnel based on behavioral patterns and hybrid work schedules that include working from home and working at an office at different times.

According to an aspect of the present disclosure, a method for generating a seat allocation plan is provided. The method is implemented by at least one processor. The method includes: receiving, by the at least one processor, a floorplan that corresponds to a floor of a building; analyzing, by the at least one processor, the floorplan in order to determine a number of seats and to identify locations of the seats and locations of non-seating areas; receiving, by the at least one processor, a first input that includes information that relates to a plurality of persons for which seat allocations are to be made; and determining, by the at least one processor based on a result of the analyzing and the first input, a seat allocation plan.

The determining of the seat allocation plan may include applying an artificial Intelligence (AI) algorithm that implements a Mixed Integer Programming and Constraint Reasoning technique with respect to the result of the analyzing and the first input.

The analyzing may further include determining distances between the locations of the seats and the locations of the non-seating areas.

The first input may further include information that relates to at least one respective group with which a corresponding one of the plurality of persons is associated. The determining of the seat allocation plan may be further based on optimizing a proximity of the locations of the seats allocated to persons within the at least one respective group.

The at least one respective group may include a plurality of groups. The first input may further include information that relates to at least one hierarchical level with which a corresponding one of the plurality of groups is associated. The determining of the seat allocation plan may be further based on allocating seats to the plurality of groups in an order of the at least one hierarchical level with which the corresponding one of the plurality of groups is associated.

The first input may further include information that relates to at least one hierarchical level with which a corresponding one of the plurality of persons is associated. The determining of the seat allocation plan is further based on allocating seats to the plurality of persons in an order of the at least one hierarchical level with which the corresponding one of the plurality of persons is associated.

The method may further include displaying, on a graphical user interface, an image that illustrates a result of the determining of the seat allocation plan.

The method may further include receiving, by the at least one processor, a second input that includes information that relates to constraints that are mandatory and information that relates to preferences that are not mandatory. The determining of the seat allocation plan is further based on the second input.

The method may further include receiving, by the at least one processor, a third input that includes information defining a template corresponding to seating areas in the floorplan. The analyzing further comprises using the third input and computer vision template matching to detect the locations of the seating areas in the floorplan by matching the template to corresponding figures in the floorplan.

The method may further include displaying via a GUI, a prompt that facilitates receiving a third input that includes at least one adjustment to the information included in the first input; determining, by the at least one processor based on the third input, an updated seat allocation plan; and displaying, via the GUI, a result of the determining of the updated seat allocation plan.

According to another aspect of the present disclosure, a computing apparatus for automatically assigning seats to a group of persons is provided. The computing apparatus includes a processor; a memory; a display; and a communication interface coupled to each of the processor, the memory, and the display. The processor is configured to: receive, via the communication interface, a floorplan that corresponds to a floor of a building; analyze the floorplan in order to determine a number of seats and to identify locations of the seats and locations of non-seating areas; receive, via the communication interface, a first input that includes information that relates to a plurality of persons for which seat allocations are to be made; and determine, based on a result of the analyzing and the first input, a seat allocation plan.

The processor may be further configured to determine the seat allocation plan by applying an artificial Intelligence (AI) algorithm that implements a Mixed Integer Programming and Constraint Reasoning technique with respect to the result of the analysis and the first input.

The processor may be further configured to determine distances between the locations of the seats and the locations of the non-seating areas.

The first input may further include information that relates to at least one respective group with which a corresponding one of the plurality of persons is associated. The determining of the seat allocation plan may be further based on optimizing a proximity of the locations of the seats allocated to persons within the at least one respective group.

The at least one respective group may include a plurality of groups. The first input may further include information that relates to at least one hierarchical level with which a corresponding one of the plurality of groups is associated. The determining of the seat allocation plan may be further based on allocating seats to the plurality of groups in an order of the at least one hierarchical level with which the corresponding one of the plurality of groups is associated.

The first input may include information that relates to at least one hierarchical level with which a corresponding one of the plurality of persons is associated. The determining of the seat allocation plan may be further based on allocating seats to the plurality of persons in an order of the at least one hierarchical level with which the corresponding one of the plurality of persons is associated.

The processor may be further configured to cause the display to display, via a graphical user interface (GUI), a result of the determining of the seat allocation plan.

The processor may be further configured to receive, via the communication interface, a second input that includes information that relates to constraints that are mandatory and information that relates to preferences that are not mandatory. The determining of the seat allocation plan may be further based on the second input.

The processor may be further configured to receive, via the communication interface, a third input that includes information defining a template corresponding to desks in the floorplan. The analyzing may further include using the third input and computer vision template matching to detect the locations of the desks in the floorplan by matching the template in the floorplan.

The processor may be further configured to: cause the display to display, via a GUI, a prompt that facilitates receiving a fourth input that includes at least one adjustment to the information included in the first input; determine, based on the fourth input, an updated seat allocation plan; and cause the display to display, via the GUI, a result of the determining of the updated seat allocation plan.

According to yet another aspect of the present disclosure, a non-transitory computer readable storage medium storing instructions for generating a seat allocation plan is provided. The storage medium includes executable code which, when executed by a processor, causes the processor to: receive, via the communication interface, a floorplan that corresponds to a floor of a building; analyze the floorplan in order to determine a number of seats and to identify locations of the seats and locations of non-seating areas; receive, via the communication interface, a first input that includes information that relates to a plurality of persons for which seat allocations are to be made; and determine, based on a result of the analyzing and the first input, a seat allocation plan.

When executed by the processor, the executable code may further cause the processor to determine the seat allocation plan by applying an artificial intelligence (AI) algorithm that implements a Mixed Integer Programming and Constraint Reasoning technique with respect to the result of the analyzing and the first input.

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates an exemplary computer system.

FIG. 2 illustrates an exemplary diagram of a network environment.

FIG. 3 shows an exemplary system for implementing a method for using artificial intelligence techniques to analyze floorplans to identify seating locations and generate a seat allocation plan for a population that uses space efficiently while respecting many different preferences and constraints.

FIG. 4 is a flowchart of an exemplary process for implementing a method for using artificial intelligence techniques to analyze floorplans to identify seating locations and generate a seat allocation plan for a population that uses space efficiently while respecting many different preferences and constraints.

FIG. 5 is a flow diagram that illustrates a process logic in a method for using artificial intelligence techniques to analyze floorplans to identify seating locations and generate a seat allocation plan for a population that uses space efficiently while respecting many different preferences and constraints, according to an exemplary embodiment.

FIG. 6 is a flow diagram that illustrates a sample hierarchical structure in a method for using artificial intelligence techniques to analyze floorplans to identify seating locations and generate a seat allocation plan for a population that uses space efficiently while respecting many different preferences and constraints, according to an exemplary embodiment.

### DETAILED DESCRIPTION

Through one or more of its various aspects, embodiments and/or specific features or sub-components of the present disclosure, are intended to bring out one or more of the advantages as specifically described above and noted below.

The examples may also be embodied as one or more non-transitory computer readable media having instructions stored thereon for one or more aspects of the present technology as described and illustrated by way of the examples herein. The instructions in some examples include executable code that, when executed by one or more processors, cause the processors to carry out steps necessary to implement the methods of the examples of this technology that are described and illustrated herein.

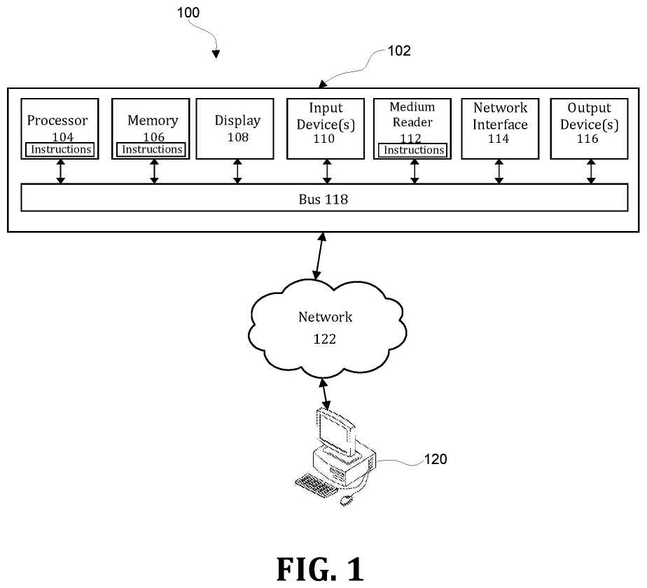

FIG. 1 is an exemplary system for use in accordance with the embodiments described herein. The system 100 is generally shown and may include a computer system 102, which is generally indicated.

The computer system 102 may include a set of instructions that can be executed to cause the computer system 102 to perform any one or more of the methods or computer-based functions disclosed herein, either alone or in combination with the other described devices. The computer system 102 may operate as a standalone device or may be connected to other systems or peripheral devices. For example, the computer system 102 may include, or be included within, any one or more computers, servers, systems, communication networks or cloud environment. Even further, the instructions may be operative in such cloud-based computing environment.

In a networked deployment, the computer system 102 may operate in the capacity of a server or as a client user computer in a server-client user network environment, a client user computer in a cloud computing environment, or as a peer computer system in a peer-to-peer (or distributed) network environment. The computer system 102, or portions thereof, may be implemented as, or incorporated into, various devices, such as a personal computer, a tablet computer, a set-top box, a personal digital assistant, a mobile device, a palmtop computer, a laptop computer, a desktop computer, a communications device, a wireless smart phone, a personal trusted device, a wearable device, a global positioning satellite (GPS) device, a web appliance, or any other machine capable of executing a set of instructions (sequential or otherwise) that specify actions to be taken by that machine. Further, while a single computer system 102 is illustrated, additional embodiments may include any collection of systems or sub-systems that individually or jointly execute instructions or perform functions. The term “system” shall be taken throughout the present disclosure to include any collection of systems or sub-systems that individually or jointly execute a set, or multiple sets, of instructions to perform one or more computer functions.

As illustrated in FIG. 1, the computer system 102 may include at least one processor 104. The processor 104 is tangible and non-transitory. As used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The processor 104 is an article of manufacture and/or a machine component. The processor 104 is configured to execute software instructions in order to perform functions as described in the various embodiments herein. The processor 104 may be a general-purpose processor or may be part of an application specific integrated circuit (ASIC). The processor 104 may also be a microprocessor, a microcomputer, a processor chip, a controller, a microcontroller, a digital signal processor (DSP), a state machine, or a programmable logic device. The processor 104 may also be a logical circuit, including a programmable gate array (PGA) such as a field programmable gate array (FPGA), or another type of circuit that includes discrete gate and/or transistor logic. The processor 104 may be a central processing unit (CPU), a graphics processing unit (GPU), or both. Additionally, any processor described herein may include multiple processors, parallel processors, or both. Multiple processors may be included in, or coupled to, a single device or multiple devices.

The computer system 102 may also include a computer memory 106. The computer memory 106 may include a static memory, a dynamic memory, or both in communication. Memories described herein are tangible storage mediums that can store data as well as executable instructions and are non-transitory during the time instructions are stored therein. Again, as used herein, the term “non-transitory” is to be interpreted not as an eternal characteristic of a state, but as a characteristic of a state that will last for a period of time. The term “non-transitory” specifically disavows fleeting characteristics such as characteristics of a particular carrier wave or signal or other forms that exist only transitorily in any place at any time. The memories are an article of manufacture and/or machine component. Memories described herein are computer-readable mediums from which data and executable instructions can be read by a computer. Memories as described herein may be random access memory (RAM), read only memory (ROM), flash memory, electrically programmable read only memory (EPROM), electrically erasable programmable read-only memory (EEPROM), registers, a hard disk, a cache, a removable disk, tape, compact disk read only memory (CD-ROM), digital versatile disk (DVD), floppy disk, blu-ray disk, or any other form of storage medium known in the art. Memories may be volatile or non-volatile, secure and/or encrypted, unsecure and/or unencrypted. Of course, the computer memory 106 may comprise any combination of memories or a single storage.

The computer system 102 may further include a display 108, such as a liquid crystal display (LCD), an organic light emitting diode (OLED), a flat panel display, a solid state display, a cathode ray tube (CRT), a plasma display, or any other type of display, examples of which are well known to skilled persons.

The computer system 102 may also include at least one input device 110, such as a keyboard, a touch-sensitive input screen or pad, a speech input, a mouse, a remote control device having a wireless keypad, a microphone coupled to a speech recognition engine, a camera such as a video camera or still camera, a cursor control device, a global positioning system (GPS) device, an altimeter, a gyroscope, an accelerometer, a proximity sensor, or any combination thereof. Those skilled in the art appreciate that various embodiments of the computer system 102 may include multiple input devices 110. Moreover, those skilled in the art further appreciate that the above-listed, exemplary input devices 110 are not meant to be exhaustive and that the computer system 102 may include any additional, or alternative, input devices 110.

The computer system 102 may also include a medium reader 112 which is configured to read any one or more sets of instructions, e.g. software, from any of the memories described herein. The instructions, when executed by a processor, can be used to perform one or more of the methods and processes as described herein. In a particular embodiment, the instructions may reside completely, or at least partially, within the memory 106, the medium reader 112, and/or the processor 110 during execution by the computer system 102.

Furthermore, the computer system 102 may include any additional devices, components, parts, peripherals, hardware, software or any combination thereof which are commonly known and understood as being included with or within a computer system, such as, but not limited to, a network interface 114 and an output device 116. The output device 116 may be, but is not limited to, a speaker, an audio out, a video out, a remote-control output, a printer, or any combination thereof.

Each of the components of the computer system 102 may be interconnected and communicate via a bus 118 or other communication link. As illustrated in FIG. 1, the components may each be interconnected and communicate via an internal bus. However, those skilled in the art appreciate that any of the components may also be connected via an expansion bus. Moreover, the bus 118 may enable communication via any standard or other specification commonly known and understood such as, but not limited to, peripheral component interconnect, peripheral component interconnect express, parallel advanced technology attachment, serial advanced technology attachment, etc.

The computer system 102 may be in communication with one or more additional computer devices 120 via a network 122. The network 122 may be, but is not limited to, a local area network, a wide area network, the Internet, a telephony network, a short-range network, or any other network commonly known and understood in the art. The short-range network may include, for example, Bluetooth, Zigbee, infrared, near field communication, ultraband, or any combination thereof. Those skilled in the art appreciate that additional networks 122 which are known and understood may additionally or alternatively be used and that the exemplary networks 122 are not limiting or exhaustive. Also, while the network 122 is illustrated in FIG. 1 as a wireless network, those skilled in the art appreciate that the network 122 may also be a wired network.

The additional computer device 120 is illustrated in FIG. 1 as a personal computer. However, those skilled in the art appreciate that, in alternative embodiments of the present application, the computer device 120 may be a laptop computer, a tablet PC, a personal digital assistant, a mobile device, a palmtop computer, a desktop computer, a communications device, a wireless telephone, a personal trusted device, a web appliance, a server, or any other device that is capable of executing a set of instructions, sequential or otherwise, that specify actions to be taken by that device. Of course, those skilled in the art appreciate that the above-listed devices are merely exemplary devices and that the device 120 may be any additional device or apparatus commonly known and understood in the art without departing from the scope of the present application. For example, the computer device 120 may be the same or similar to the computer system 102. Furthermore, those skilled in the art similarly understand that the device may be any combination of devices and apparatuses.

Of course, those skilled in the art appreciate that the above-listed components of the computer system 102 are merely meant to be exemplary and are not intended to be exhaustive and/or inclusive. Furthermore, the examples of the components listed above are also meant to be exemplary and similarly are not meant to be exhaustive and/or inclusive.

In accordance with various embodiments of the present disclosure, the methods described herein may be implemented using a hardware computer system that executes software programs. Further, in an exemplary, non-limited embodiment, implementations can include distributed processing, component/object distributed processing, and parallel processing. Virtual computer system processing can be constructed to implement one or more of the methods or functionalities as described herein, and a processor described herein may be used to support a virtual processing environment.

As described herein, various embodiments provide optimized methods and systems for using artificial intelligence techniques to analyze floorplans to identify seating locations and generate a seat allocation plan for a population that uses space efficiently while respecting many different preferences and constraints.

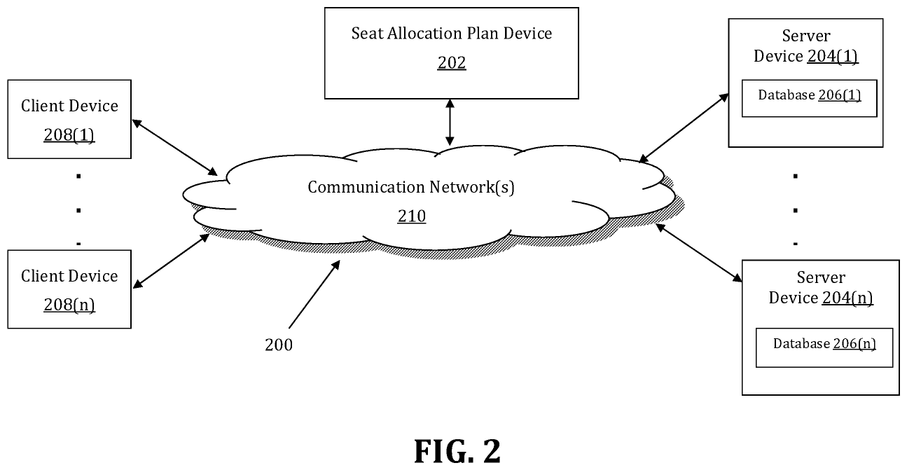

Referring to FIG. 2, a schematic of an exemplary network environment 200 for implementing a method for using artificial intelligence techniques to analyze floorplans to identify seating locations and generate a seat allocation plan for a population that uses space efficiently while respecting many different preferences and constraints is illustrated. In an exemplary embodiment, the method is executable on any networked computer platform, such as, for example, a personal computer (PC).

The method for using artificial intelligence techniques to analyze floorplans to identify seating locations and generate a seat allocation plan for a population that uses space efficiently while respecting many different preferences and constraints may be implemented by a Seat Allocation Plan (SAP) device 202. The SAP device 202 may be the same or similar to the computer system 102 as described with respect to FIG. 1. The SAP device 202 may store one or more applications that can include executable instructions that, when executed by the SAP device 202, cause the SAP device 202 to perform actions, such as to transmit, receive, or otherwise process network messages, for example, and to perform other actions described and illustrated below with reference to the figures. The application(s) may be implemented as modules or components of other applications. Further, the application(s) can be implemented as operating system extensions, modules, plugins, or the like.

Even further, the application(s) may be operative in a cloud-based computing environment. The application(s) may be executed within or as virtual machine(s) or virtual server(s) that may be managed in a cloud-based computing environment. Also, the application(s), and even the SAP device 202 itself, may be located in virtual server(s) running in a cloud-based computing environment rather than being tied to one or more specific physical network computing devices. Also, the application(s) may be running in one or more virtual machines (VMs) executing on the SAP device 202. Additionally, in one or more embodiments of this technology, virtual machine(s) running on the SAP device 202 may be managed or supervised by a hypervisor.

In the network environment 200 of FIG. 2, the SAP device 202 is coupled to a plurality of server devices 204(1)-204(n) that hosts a plurality of databases 206(1)-206(n), and also to a plurality of client devices 208(1)-208(n) via communication network(s) 210. A communication interface of the SAP device 202, such as the network interface 114 of the computer system 102 of FIG. 1, operatively couples and communicates between the SAP device 202, the server devices 204(1)-204(n), and/or the client devices 208(1)-208(n), which are all coupled together by the communication network(s) 210, although other types and/or numbers of communication networks or systems with other types and/or numbers of connections and/or configurations to other devices and/or elements may also be used.

The communication network(s) 210 may be the same or similar to the network 122 as described with respect to FIG. 1, although the SAP device 202, the server devices 204(1)-204(n), and/or the client devices 208(1)-208(n) may be coupled together via other topologies. Additionally, the network environment 200 may include other network devices such as one or more routers and/or switches, for example, which are well known in the art and thus will not be described herein. This technology provides a number of advantages including methods, non-transitory computer readable media, and SAP devices that efficiently implement a method for using artificial intelligence techniques to analyze floorplans to identify seating locations and generate a seat allocation plan for a population that uses space efficiently while respecting many different preferences and constraints.

By way of example only, the communication network(s) 210 may include local area network(s) (LAN(s)) or wide area network(s) (WAN(s)), and can use TCP/IP over Ethernet and industry-standard protocols, although other types and/or numbers of protocols and/or communication networks may be used. The communication network(s) 210 in this example may employ any suitable interface mechanisms and network communication technologies including, for example, teletraffic in any suitable form (e.g., voice, modem, and the like), Public Switched Telephone Network (PSTNs), Ethernet-based Packet Data Networks (PDNs), combinations thereof, and the like.

The SAP device 202 may be a standalone device or integrated with one or more other devices or apparatuses, such as one or more of the server devices 204(1)-204(n), for example. In one particular example, the SAP device 202 may include or be hosted by one of the server devices 204(1)-204(n), and other arrangements are also possible. Moreover, one or more of the devices of the SAP device 202 may be in a same or a different communication network including one or more public, private, or cloud networks, for example.

The plurality of server devices 204(1)-204(n) may be the same or similar to the computer system 102 or the computer device 120 as described with respect to FIG. 1, including any features or combination of features described with respect thereto. For example, any of the server devices 204(1)-204(n) may include, among other features, one or more processors, a memory, and a communication interface, which are coupled together by a bus or other communication link, although other numbers and/or types of network devices may be used. The server devices 204(1)-204(n) in this example may process requests received from the SAP device 202 via the communication network(s) 210 according to the HTTP-based and/or JavaScript Object Notation (JSON) protocol, for example, although other protocols may also be used.

The server devices 204(1)-204(n) may be hardware or software or may represent a system with multiple servers in a pool, which may include internal or external networks. The server devices 204(1)-204(n) hosts the databases 206(1)-206(n) that are configured to store data that relates to floorplans and data that relates to personnel requirements and preferences.

Although the server devices 204(1)-204(n) are illustrated as single devices, one or more actions of each of the server devices 204(1)-204(n) may be distributed across one or more distinct network computing devices that together comprise one or more of the server devices 204(1)-204(n). Moreover, the server devices 204(1)-204(n) are not limited to a particular configuration. Thus, the server devices 204(1)-204(n) may contain a plurality of network computing devices that operate using a master/slave approach, whereby one of the network computing devices of the server devices 204(1)-204(n) operates to manage and/or otherwise coordinate operations of the other network computing devices.

The server devices 204(1)-204(n) may operate as a plurality of network computing devices within a cluster architecture, a peer-to peer architecture, virtual machines, or within a cloud architecture, for example. Thus, the technology disclosed herein is not to be construed as being limited to a single environment and other configurations and architectures are also envisaged.

The plurality of client devices 208(1)-208(n) may also be the same or similar to the computer system 102 or the computer device 120 as described with respect to FIG. 1, including any features or combination of features described with respect thereto. For example, the client devices 208(1)-208(n) in this example may include any type of computing device that can interact with the SAP device 202 via communication network(s) 210. Accordingly, the client devices 208(1)-208(n) may be mobile computing devices, desktop computing devices, laptop computing devices, tablet computing devices, virtual machines (including cloud-based computers), or the like, that host chat, e-mail, or voice-to-text applications, for example. In an exemplary embodiment, at least one client device 208 is a wireless mobile communication device, i.e., a smart phone.

The client devices 208(1)-208(n) may run interface applications, such as standard web browsers or standalone client applications, which may provide an interface to communicate with the SAP device 202 via the communication network(s) 210 in order to communicate user requests and information. The client devices 208(1)-208(n) may further include, among other features, a display device, such as a display screen or touchscreen, and/or an input device, such as a keyboard, for example.

Although the exemplary network environment 200 with the SAP device 202, the server devices 204(1)-204(n), the client devices 208(1)-208(n), and the communication network(s) 210 are described and illustrated herein, other types and/or numbers of systems, devices, components, and/or elements in other topologies may be used. It is to be understood that the systems of the examples described herein are for exemplary purposes, as many variations of the specific hardware and software used to implement the examples are possible, as will be appreciated by those skilled in the relevant art(s).

One or more of the devices depicted in the network environment 200, such as the SAP device 202, the server devices 204(1)-204(n), or the client devices 208(1)-208(n), for example, may be configured to operate as virtual instances on the same physical machine. In other words, one or more of the SAP device 202, the server devices 204(1)-204(n), or the client devices 208(1)-208(n) may operate on the same physical device rather than as separate devices communicating through communication network(s) 210. Additionally, there may be more or fewer SAP devices 202, server devices 204(1)-204(n), or client devices 208(1)-208(n) than illustrated in FIG. 2.

In addition, two or more computing systems or devices may be substituted for any one of the systems or devices in any example. Accordingly, principles and advantages of distributed processing, such as redundancy and replication also may be implemented, as desired, to increase the robustness and performance of the devices and systems of the examples. The examples may also be implemented on computer system(s) that extend across any suitable network using any suitable interface mechanisms and traffic technologies, including by way of example only teletraffic in any suitable form (e.g., voice and modem), wireless traffic networks, cellular traffic networks, Packet Data Networks (PDNs), the Internet, intranets, and combinations thereof.

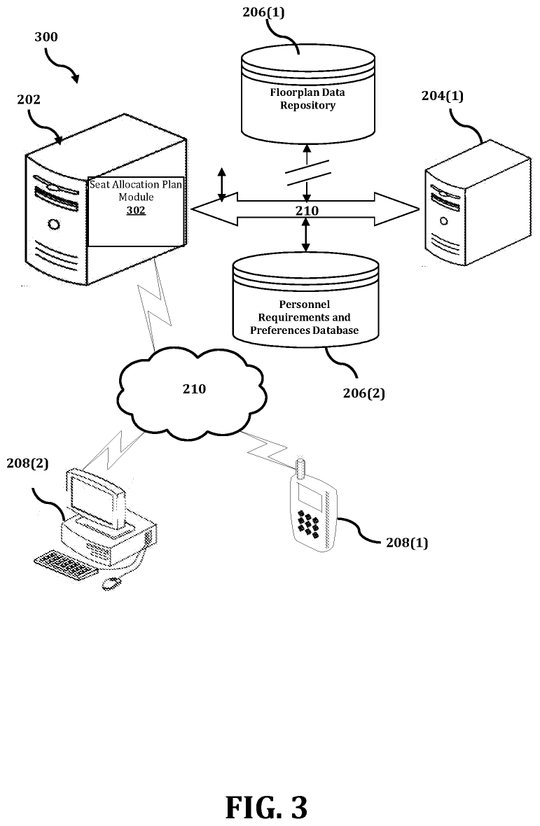

The SAP device 202 is described and illustrated in FIG. 3 as including a seat allocation plan module 302, although it may include other rules, policies, modules, databases, or applications, for example. As will be described below, the seat allocation plan module 302 is configured to implement a method for using artificial intelligence techniques to analyze floorplans to identify seating locations and generate a seat allocation plan for a population that uses space efficiently while respecting many different preferences and constraints.

An exemplary process 300 for implementing a mechanism for using artificial intelligence techniques to analyze floorplans to identify seating locations and generate a seat allocation plan for a population that uses space efficiently while respecting many different preferences and constraints by utilizing the network environment of FIG. 2 is illustrated as being executed in FIG. 3. Specifically, a first client device 208(1) and a second client device 208(2) are illustrated as being in communication with SAP device 202. In this regard, the first client device 208(1) and the second client device 208(2) may be “clients” of the SAP device 202 and are described herein as such. Nevertheless, it is to be known and understood that the first client device 208(1) and/or the second client device 208(2) need not necessarily be “clients” of the SAP device 202, or any entity described in association therewith herein. Any additional or alternative relationship may exist between either or both of the first client device 208(1) and the second client device 208(2) and the SAP device 202, or no relationship may exist.

Further, SAP device 202 is illustrated as being able to access a floorplan data repository 206(1) and a personnel requirements and preferences database 206(2). The seat allocation plan module 302 may be configured to access these databases for implementing a method for using artificial intelligence techniques to analyze floorplans to identify seating locations and generate a seat allocation plan for a population that uses space efficiently while respecting many different preferences and constraints.

The first client device 208(1) may be, for example, a smart phone. Of course, the first client device 208(1) may be any additional device described herein. The second client device 208(2) may be, for example, a personal computer (PC). Of course, the second client device 208(2) may also be any additional device described herein.

The process may be executed via the communication network(s) 210, which may comprise plural networks as described above. For example, in an exemplary embodiment, either or both of the first client device 208(1) and the second client device 208(2) may communicate with the SAP device 202 via broadband or cellular communication. Of course, these embodiments are merely exemplary and are not limiting or exhaustive.

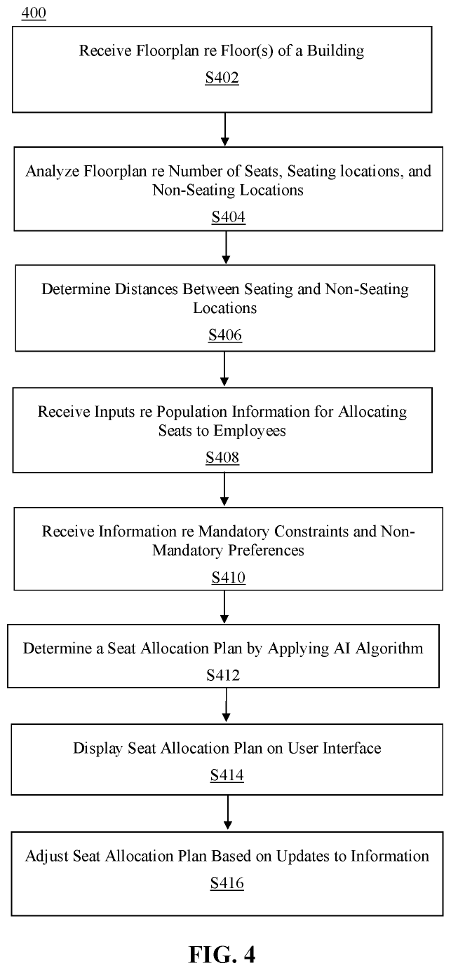

Upon being started, the seat allocation plan module 302 executes a process for using artificial intelligence techniques to analyze floorplans to identify seating locations and generate a seat allocation plan for a population that uses space efficiently while respecting many different preferences and constraints. An exemplary process for using artificial intelligence techniques to analyze floorplans to identify seating locations and generate a seat allocation plan for a population that uses space efficiently while respecting many different preferences and constraints is generally indicated at flowchart 400 in FIG. 4.

In process 400 of FIG. 4, at step S402, the seat allocation plan module 302 receives at least one floorplan of one or more floors of a building. In an exemplary embodiment, the floorplan visually depicts all the seats and offices on the floor. In an exemplary embodiment, the floorplans may be provided in any one or more of a variety of different image formats, such as, for example, jpeg, pdf, CAD-drawings, or any other suitable machine-readable image file type. In an exemplary embodiment, the floorplans may include, for example, information about the placement of desks and offices, and other floor specific information such as locations of restrooms, elevators, and structural walls, amongst others. In an exemplary embodiment, the provided floorplans may have a visual reference or “pattern” indicating a specific placement of desks, offices, and/or other designated seating areas. In an exemplary embodiment, the floorplans may be procured from internal real estate management systems, or directly from the architects.

At step S404, the seat allocation plan module 302 analyzes the floorplan(s) to determine the number of seats, seating locations, and/or non-seating locations. In an exemplary embodiment, the overall approach is flexible in supporting the identification of seats, offices, and/or other seating areas from the floorplan(s) provided. In an exemplary embodiment, the seat allocation plan module 302 receives a template specification, in which the user specifies one or more visual templates (i.e., patterns) for desks, offices, and/or other seating areas on the floorplan(s). The seat allocation plan module 302 then uses computer vision techniques, including computer vision template matching, to match the provided template(s) to the floorplan(s) in order to determine desk, office, and/or other seating area positions within the respective floorplan(s). In an exemplary embodiment, the desk, office, and/or other seating areas are matched based on their unique templates/identifiers. In an exemplary embodiment, obstructions and/or other non-seating area locations may be inferred from the floorplans provided by the users. In an exemplary embodiment, the obstructions and/or other non-seating area locations may be identified with computer vision techniques using edge detection. The computer vision techniques may include one or more algorithms for identifying edges and/or corners in the processed image based on changes and/or discontinuities at points in the image in which the brightness changes sharply.

At step S406 the seat allocation plan module 302 determines the distances between seating and non-seating locations based on the analysis performed in step S404. In an exemplary embodiment, the distance between seats is calculated by using a connected graph generated by an algorithm. In an exemplary embodiment, the seat allocation plan module 302 uses a “rapidly-exploring random tree” (RRT) to find valid “way points” in the floorplan. Away point is valid if it is connected to another way point, and the path between the way points is not intersected by a wall and/or other obstruction. In an exemplary embodiment, by using the fully connected graph, the distance between any respective pair of seats may be computed. In an exemplary embodiment, the distance is unitless and the seat allocation plan module 302 generates a relative “walkable” distance between any particular pair of seats. In an exemplary embodiment, the user may choose to penalize seats that require the traversal of doors, by adding a penalty in their distance.

Then, at step S408, the seat allocation plan module 302 receives a first set of data that relates to the population information for the plurality of persons for which the seat allocations are made. In an exemplary embodiment, a graphical user interface (GUI) may be displayed on a screen, and a user may be prompted to enter one or more files that include population information. The population information may include, for example, any one or more of names of the plurality of persons, a team or group to which each person belongs and/or a department or other organization to which each person is assigned, a work status such as full-time or part-time, and/or any other suitable types of information that relate to each person and/or group. In an exemplary embodiment, the population information input is provided in a standard tabular format (e.g., a spreadsheet). The population information input may also include, for example, general identification information (i.e., id, name), business-related information (i.e., management hierarchy, number of desks needed, number of offices needed, segregation status), and/or team/group classification information (i.e., team/group hierarchy, team/group synergies). In an exemplary embodiment, this information can be extracted from internal HR (Human Resources) systems. In an exemplary embodiment, individual persons may be associated with a group/team and the population information may include information corresponding to each team's location in the organizational hierarchy and/or any larger team to which they belong. Each hierarchy level can be seen as a collection of teams that are allocated sequentially, and the desk and office requirements are the sum of the team's descendants.

At step S410, the seat allocation plan module 302 receives a second set of data that relates to mandatory constraints and non-mandatory preferences. In an exemplary embodiment, the user may be prompted by the GUI to enter one or more files that include constraints that are mandatory and/or preferences. The mandatory constraints may include, for example, specific seat and office requirements for each team, specific seat requirements for individuals and/or teams, and/or any other requirements that pertain to a particular person and/or particular team. The non-mandatory preferences may include, for example, constructive collaboration preferences regarding which teams have closer synergies with other teams (e.g., teams with higher synergies are allocated seats closer together). The non-mandatory preferences may also include personal preferences regarding which day(s) of the week particular persons and/or teams are scheduled to occupy space within the building, preferences regarding proximity of a particular person to at least one other person, preferences regarding proximity of a particular team to at least one other team, preferences regarding spatial proximity between teams (e.g., a preference that a particular team be situated relatively nearby to another team), and/or any other types of preferences that relate to space allocation and scheduling. The constraints and preferences may be specified at either or both of an individual level and/or a team level.

In an exemplary embodiment, the floorplan contains one or more areas that may be seen as segregated or non-seating areas that have been separated for compliance, legal or other reasons. The teams allocated in each segregated area must be separated from the rest of the teams on the same floor in other areas. The algorithm may identify these separate areas dynamically, as each area is separated by doors which can be represented as an obstruction in the way point generation scheme. Thus, by randomly starting the way point generation algorithm, these separate areas can be identified, as they will not be reachable by any other areas given the obstructions. The labeling of the areas may be inferred based on the allocation demand of the teams that have to be allocated to each segregated area.

At step S412, the seat allocation plan module 302 uses each of the results of the analysis of the floorplan, the first set of data, and the second set of data to determine a seat allocation plan within the building for the plurality of people. In an exemplary embodiment, the determination of the seat allocation plan is effected by applying an artificial intelligence (AI) algorithm that is configured to satisfy all of the mandatory constraints and to optimize a satisfaction of the preferences.

In an exemplary embodiment, the step of determining the seat allocation plan is framed as an optimization problem with integer variables (e.g., a Mixed Integer Linear Program). In an exemplary embodiment, the AI algorithm is configured to solve this optimization problem by finding a solution that minimizes a given objective function (e.g., seats of the same team are as close together as possible) while satisfying all the constraints imposed. In an exemplary embodiment, the objective function that evaluates a given allocation of seats may be based on metrics, including cohesiveness and average distance to offices. In an exemplary embodiment, cohesiveness is the main metric considered and is based on the average distance between seats allocated to each team (i.e., the smaller the distance, the better). In an exemplary embodiment, the average distance to offices is a secondary metric that considers the maximum distance from a team's allocated seat to their allocated office (i.e., the smaller this distance, the better).

In an exemplary embodiment, the formulation of the optimization problem for determining the seat allocation plan may include using a Dynamic Programming Scheme that allows for the incorporation of an organizational hierarchy. In an embodiment, each hierarchy level of the organizational hierarchy may be seen as a collection of teams that must be allocated sequentially, where the desk and office requirement are the sum of the team's descendants. In this embodiment, teams are allocated sequentially, in the seat allocation plan, based on their level in the organizational hierarchy. For example, in step one, seats and offices are allocated to the top-level team in the organizational hierarchy by the seat allocation plan module 302. In step two, the seats and offices are allocated to the next level of the organizational hierarchy by using the seats and offices allocated to the parent team in the previous iteration. In step three, the seat allocation plan module 302 goes to the next level of the hierarchy and repeats steps two and three until all teams have been allocated. By using the process outlined above, the seat allocation of teams is planned on each level by only using the previous level's seats and offices as assigned.

At step S414, the seat allocation plan module 302 displays, via the GUI, a result of the determination of the seat allocation plan. In an exemplary embodiment, the GUI may display a seat allocation plan for the floor of a building by team assignment. The GUI may display pictorial depictions of floor plans that illustrate locations of seats and offices within the particular floor along with color-coded notations that indicate occupancy by persons that belong to certain teams. For example, in exemplary embodiments, each team may be depicted as a particular color and the GUI may display the floorplan with each desk and/or office highlighted with the corresponding color for the team allocated to that particular desk or office.

At step S416, the seat allocation plan module 302 adjusts the seat allocation plan based on updated information that relates to the personnel, the building, the organizational hierarchy, the mandatory constraints, and/or the preferences. In an exemplary embodiment, the GUI includes a prompt that enables a user to enter updated data upon which an adjustment to the allocation and/or the schedule may be based. In an exemplary embodiment, a user may move teams and/or individual seats via drag and drop to a different location based on latent preferences.

In an exemplary embodiment, the GUI may selectively display the seat allocation plan at multiple different levels of view. For example, in an exemplary embodiment, the GUI may selectively be switched between different views of the floorplan based on the selected corresponding hierarchy level. Additionally, this allows the user to selectively view the floorplan at various levels of detail or granularity required for use. In an exemplary embodiment, the selected floorplan view may be downloaded to a useable form. In an exemplary embodiment, the floorplan may be downloaded in different formats and may also be exported into presentations, documents, and other formats. In an exemplary embodiment, the user may draw walls on the floorplan to indicate the intent to build a segregation wall.

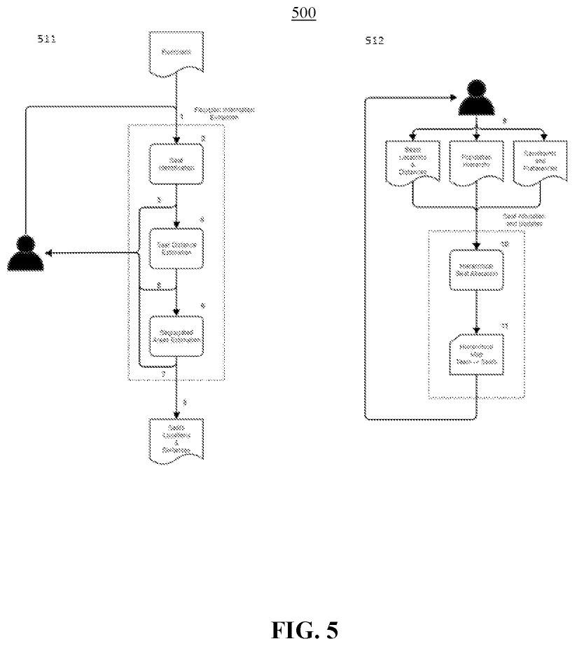

FIG. 5 is a flow diagram 500 that illustrates a process logic in a method for using artificial intelligence techniques to analyze floorplans to identify seating locations and generate a seat allocation plan for a population that uses space efficiently while respecting many different preferences and constraints, according to an exemplary embodiment. The process may be split into two stages. The first stage is the Floorplan Information Extraction stage 511, where seat information is extracted, such as, for example, location and class (i.e., desk/office). The second stage is the Seat Allocation and Updates stage 512, where the seat information is used to plan an allocation of seats to teams, and to visualize the aforementioned allocation. In summary, the Floorplan Information Extraction stage 511 starts with step 1, by a user utilizing the AI system to automatically process visual floorplans. In step 2, a seat identification module uses computer vision techniques to automatically detect seating locations such as desks and offices from the processed visual floorplans. In step 3, the user interacts with the seat identification process, reviewing solutions and fine-tuning parameters until a complete solution is found. In step 4, an AI planner module is used to estimate a connecting graph between the different seating locations, and to estimate their relative distances. In step 5, the user interacts with the AI planner module, reviewing solutions and fine-tuning parameters until a complete solution is found. In step 6, the connecting graph is processed to determine the existence of segregated areas of seats. In step 7, the user interacts with the AI planner module, reviewing solutions and fine-tuning parameters until a complete solution is found. In step 8, the resulting 1) seat allocations; 2) seat distances; and 3) segregated areas for the floor(s) are returned to the user. Different metrics of interest may also be provided.

Referring again to FIG. 5, in the second stage, i.e., the Seat Allocation and Updates stage 512, of the process logic, the user utilizes the AI system to automatically plan the seating allocations. In step 9, the user provides as input 1) the population information; 2) the specification of different constraints and preferences; and 3) the seat information extracted previously. In step 10, a hierarchical seating allocation planner assigns seats in the floor to the teams therein and the seats are allocated in hierarchical fashion. In step 11, the resulting seat allocations are returned to the user and different metrics of interest are also provided. In the final step, the user assesses the solution generated and the associated metrics. The user may also update new preferences and constraints to generate a new solution; or directly perform manual adjustments on the current solution.

Planner—Hierarchical Seat Allocation: In an exemplary embodiment, the planner allocating teams to at least one floor relies on AI techniques based on constraint reasoning and user-defined preferences. In particular, the allocation problem may be framed as an optimization problem with integer variables—i.e., a Mixed Integer Linear Program. Solving this optimization problem corresponds to finding a solution that minimizes a given objective function while satisfying all the constraints imposed.

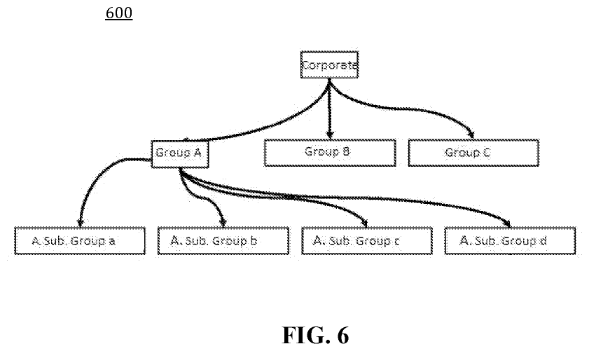

FIG. 6 illustrates an example of a team hierarchical structure 600. FIG. 6 shows that Corporate is at the highest level of the hierarchy and consists of Group A, Group B, and Group C. FIG. 6 also shows that Group A is made up of four subordinate groups or teams: A. sub. Group a, A. sub. Group b, A. sub. Group c, and A. sub. Group d. FIG. 6 depicts that, for example, in an organizational hierarchy, Sub. Group C can be seen as a team, however it is also a member of both Group A and Corporate. Each hierarchy level can be seen as a collection of teams that must be allocated sequentially, where the desk and office requirement are the sum of the team's descendants.

Additional Capabilities: In an exemplary embodiment, the seat allocation plan system and process may be improved by integrating with additional systems and taking into account further preferences and adjustments.

Integration with other office management software: In an exemplary embodiment, the seat allocation plan system and process could integrate with other software such as restacking software, visitor management system or desk booking system to optimize the overall office environment.

Personalized Seating Preferences: In an exemplary embodiment, the seat allocation plan system and process may integrate the personal preferences of each team, such as preferred location, proximity to windows, proximity to collaboration areas, or noise levels.

Real Time Seating Adjustments: In an exemplary embodiment, the seat allocation plan system and process may consider the hybrid work patterns of each team and make real-time seating adjustments based on the current office space availability.

Accordingly, with this technology, an optimized process for using artificial intelligence techniques to analyze floorplans to identify seating locations and generate a seat allocation plan for a population that uses space efficiently while respecting many different preferences and constraints.

Although the invention has been described with reference to several exemplary embodiments, it is understood that the words that have been used are words of description and illustration, rather than words of limitation. Changes may be made within the purview of the appended claims, as presently stated and as amended, without departing from the scope and spirit of the present disclosure in its aspects. Although the invention has been described with reference to particular means, materials and embodiments, the invention is not intended to be limited to the particulars disclosed; rather the invention extends to all functionally equivalent structures, methods, and uses such as are within the scope of the appended claims.

For example, while the computer-readable medium may be described as a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the embodiments disclosed herein.

The computer-readable medium may comprise a non-transitory computer-readable medium or media and/or comprise a transitory computer-readable medium or media. In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes or other storage device to capture carrier wave signals such as a signal communicated over a transmission medium. Accordingly, the disclosure is considered to include any computer-readable medium or other equivalents and successor media, in which data or instructions may be stored.

Although the present application describes specific embodiments which may be implemented as computer programs or code segments in computer-readable media, it is to be understood that dedicated hardware implementations, such as application specific integrated circuits, programmable logic arrays and other hardware devices, can be constructed to implement one or more of the embodiments described herein. Applications that may include the various embodiments set forth herein may broadly include a variety of electronic and computer systems. Accordingly, the present application may encompass software, firmware, and hardware implementations, or combinations thereof. Nothing in the present application should be interpreted as being implemented or implementable solely with software and not hardware.

Although the present specification describes components and functions that may be implemented in particular embodiments with reference to particular standards and protocols, the disclosure is not limited to such standards and protocols. Such standards are periodically superseded by faster or more efficient equivalents having essentially the same functions. Accordingly, replacement standards and protocols having the same or similar functions are considered equivalents thereof.

The illustrations of the embodiments described herein are intended to provide a general understanding of the various embodiments. The illustrations are not intended to serve as a complete description of all the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims, and their equivalents, and shall not be restricted or limited by the foregoing detailed description.

What is claimed is:

1. A method for generating a seat allocation plan, the method being implemented by at least one processor, the method comprising:
receiving, by the at least one processor, a floorplan that corresponds to a floor of a building;
analyzing, by the at least one processor, the floorplan in order to determine a number of seats and to identify locations of the seats and locations of non-seating areas;
receiving, by the at least one processor, a first input that includes information that relates to a plurality of persons for which seat allocations are to be made; and
determining, by the at least one processor based on a result of the analyzing and the first input, a seat allocation plan.

2. The method of claim 1, wherein the determining of the seat allocation plan comprises applying an artificial Intelligence (AI) algorithm that implements a Mixed Integer Programming and Constraint Reasoning technique with respect to the result of the analyzing and the first input.

3. The method of claim 1, wherein the analyzing further comprises determining distances between the locations of the seats and the locations of the non-seating areas.

4. The method of claim 1, wherein the first input further includes information that relates to at least one respective group with which a corresponding one of the plurality of persons is associated, and the determining of the seat allocation plan is further based on optimizing a proximity of the locations of the seats allocated to persons within the at least one respective group.

5. The method of claim 4, wherein the at least one respective group includes a plurality of groups;
the first input further includes information that relates to at least one hierarchical level with which a corresponding one of the plurality of groups is associated; and
the determining of the seat allocation plan is further based on allocating seats to the plurality of groups in an order of the at least one hierarchical level with which the corresponding one of the plurality of groups is associated.

6. The method of claim 1, wherein the first input includes information that relates to at least one hierarchical level with which a corresponding one of the plurality of persons is associated, and the determining of the seat allocation plan is further based on allocating seats to the plurality of persons in an order of the at least one hierarchical level with which the corresponding one of the plurality of persons is associated.

7. The method of claim 1, further comprising displaying, via a graphical user interface (GUI), a result of the determining of the seat allocation plan.

8. The method of claim 1, further comprising receiving, by the at least one processor, a second input that includes information that relates to constraints that are mandatory and information that relates to preferences that are not mandatory, and wherein the determining of the seat allocation plan is further based on the second input.

9. The method of claim 1, further comprising receiving, by at least one processor, a third input that includes information defining a template corresponding to seating areas in the floorplan, and wherein the analyzing further comprises using the third input and computer vision template matching to detect the locations of the seating areas in the floorplan by matching the template to corresponding figures in the floorplan.

10. The method of claim 1, further comprising:
displaying via a GUI, a prompt that facilitates receiving a fourth input that includes at least one adjustment to the information included in the first input;
determining, by the at least one processor based on the fourth input, an updated seat allocation plan; and
displaying, via the GUI, a result of the determining of the updated seat allocation plan.

11. A computing apparatus for generating a seat allocation plan, the computing apparatus comprising:
a processor;
a memory;
a display; and
a communication interface coupled to each of the processor, the memory, and the display,
wherein the processor is configured to:
receive, via the communication interface, a floorplan that corresponds to a floor of a building;
analyze the floorplan in order to determine a number of seats and to identify locations of the seats and locations of non-seating areas;
receive, via the communication interface, a first input that includes information that relates to a plurality of persons for which seat allocations are to be made; and
determine, based on a result of the analyzing and the first input, a seat allocation plan.

12. The computing apparatus of claim 11, wherein the processor is further configured to determine the seat allocation plan by applying an artificial Intelligence (AI) algorithm that implements a Mixed Integer Programming and Constraint Reasoning technique with respect to the result of the analysis and the first input.

13. The computing apparatus of claim 11, wherein the processor is further configured to determine distances between the locations of the seats and the locations of the non-seating areas.

14. The computing apparatus of claim 11, wherein the first input further includes information that relates to at least one respective group with which a corresponding one of the plurality of persons is associated, and the determining of the seat allocation plan is further based on optimizing a proximity of the locations of the seats allocated to persons within the at least one respective group.

15. The computing apparatus of claim 14, wherein the at least one respective group includes a plurality of groups;
the first input further includes information that relates to at least one hierarchical level with which a corresponding one of the plurality of groups is associated; and
the determining of the seat allocation plan is further based on allocating seats to the plurality of groups in an order of the at least one hierarchical level with which the corresponding one of the plurality of groups is associated.

16. The computing apparatus of claim 11, wherein the first input includes information that relates to at least one hierarchical level with which a corresponding one of the plurality of persons is associated, and the determining of the seat allocation plan is further based on allocating seats to the plurality of persons in an order of the at least one hierarchical level with which the corresponding one of the plurality of persons is associated.

17. The computing apparatus of claim 11, wherein the processor is further configured to cause the display to display, via a graphical user interface (GUI), a result of the determining of the seat allocation plan.

18. The computing apparatus of claim 11, wherein the processor is further configured to receive, via the communication interface, a second input that includes information that relates to constraints that are mandatory and information that relates to preferences that are not mandatory, and wherein the determining of the seat allocation plan is further based on the second input.

19. A non-transitory computer readable storage medium storing instructions for generating a seat allocation plan, the storage medium comprising executable code which, when executed by a processor, causes the processor to:
receive, via the communication interface, a floorplan that corresponds to a floor of a building;
analyze the floorplan in order to determine a number of seats and to identify locations of the seats and locations of non-seating areas;
receive, via the communication interface, a first input that includes information that relates to a plurality of persons for which seat allocations are to be made; and
determine, based on a result of the analyzing and the first input, a seat allocation plan.

20. The storage medium of claim 19, wherein the executable code is further configured to cause the processor to determine the seat allocation plan by applying an artificial intelligence (AI) algorithm that implements a Mixed Integer Programming and Constraint Reasoning technique with respect to the result of the analyzing and the first input.
